(19) United States
(12) Patent Application Publication
(10) Pub. No.: US 2025/0386737 A1
(43) Pub. Date: Dec. 18, 2025

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Fu-Ting SUNG, Hsinchu (TW); Min-Yung Ko, Hsinchu City (TW); Chin I Wang, Tainan City (TW); Tsung-Hsueh Yang, Taichung City (TW); Shao-Ling Chang, Hsinchu City (TW); Watson Liu, Hsinchu County (TW)

(73) Assignee: Taiwan Semiconductor Manufacturing Company, Ltd., Hsinchu (TW)

(21) Appl. No.: 18/744,673

(22) Filed: Jun. 16, 2024

(51) Int. Cl. H10N 50/80; H01L 21/02; H10B 61/00; H10N 50/01

(52) U.S. Cl. CPC H10N 50/80; H10B 61/22; H10N 50/01; H01L 21/02068

(57) ABSTRACT

A semiconductor device includes a bottom electrode, a data storage layer, a top electrode and a metal electrode. A free-energy change for an oxidation of the metal electrode is less than a free-energy change for an oxidation of the top electrode.

### BACKGROUND

Many modern day electronic devices contain electronic memory. Electronic memory may be volatile memory or non-volatile memory. Non-volatile memory is able to retain its stored data in the absence of power, whereas volatile memory loses its stored data when power is lost. Magnetoresistive random-access memory (MRAM) is one promising candidate for next generation non-volatile electronic memory due to advantages over current electronic memory. Compared to current non-volatile memory, such as flash random-access memory, MRAM typically is faster and has better endurance. Compared to current volatile memory, such as dynamic random-access memory (DRAM) and static random-access memory (SRAM), MRAM typically has similar performance and density, but lower power consumption.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1G are schematic cross-sectional views of various stages in a method of forming a semiconductor device according to some embodiments.

FIG. 2 is a schematic cross-sectional view of a semiconductor device according to some embodiments.

FIG. 3 is a schematic cross-sectional view of a semiconductor device according to some embodiments.

FIGS. 4A-4H are schematic cross-sectional views of various stages in a method of forming a semiconductor device according to some embodiments.

FIG. 5 is a schematic cross-sectional view of a semiconductor device according to some embodiments.

FIG. 6 is a schematic cross-sectional view of a semiconductor device according to some embodiments.

FIG. 7 is a schematic cross-sectional view of a semiconductor device according to some embodiments.

FIG. 8 is a schematic cross-sectional view of a semiconductor device according to some embodiments.

FIG. 9 is a flowchart of a method of forming a semiconductor device according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

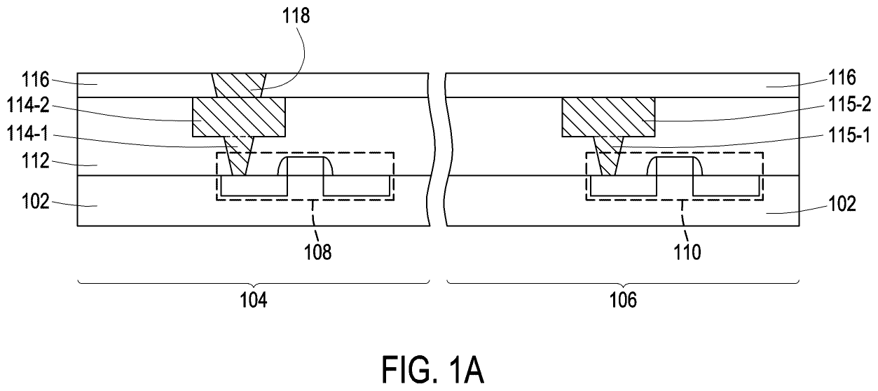

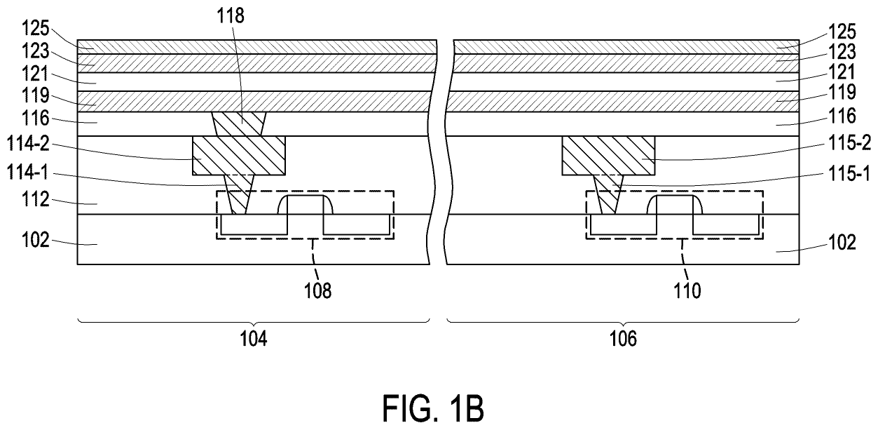

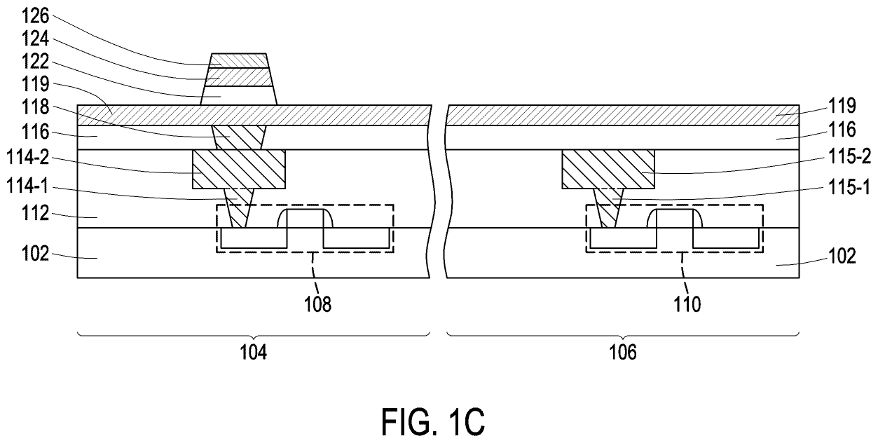

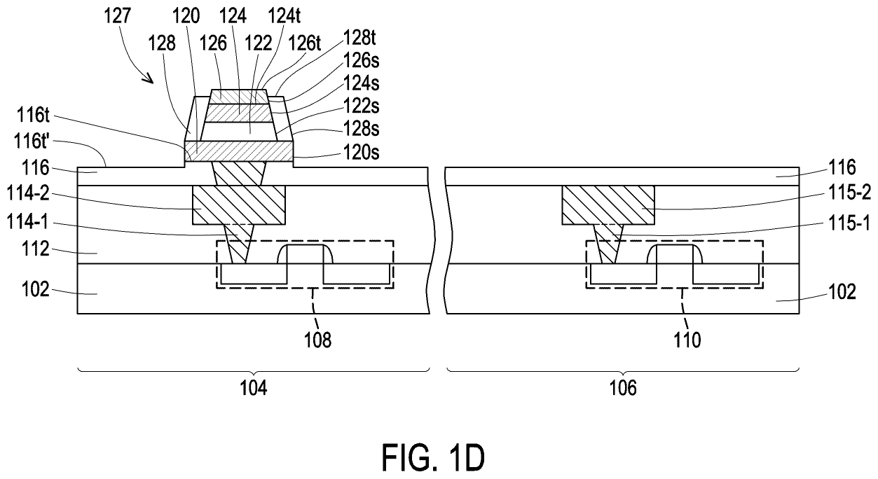

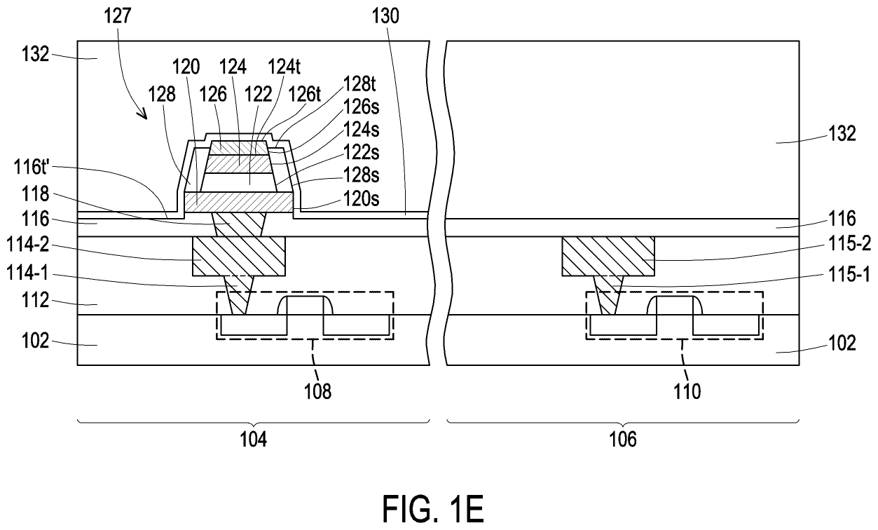

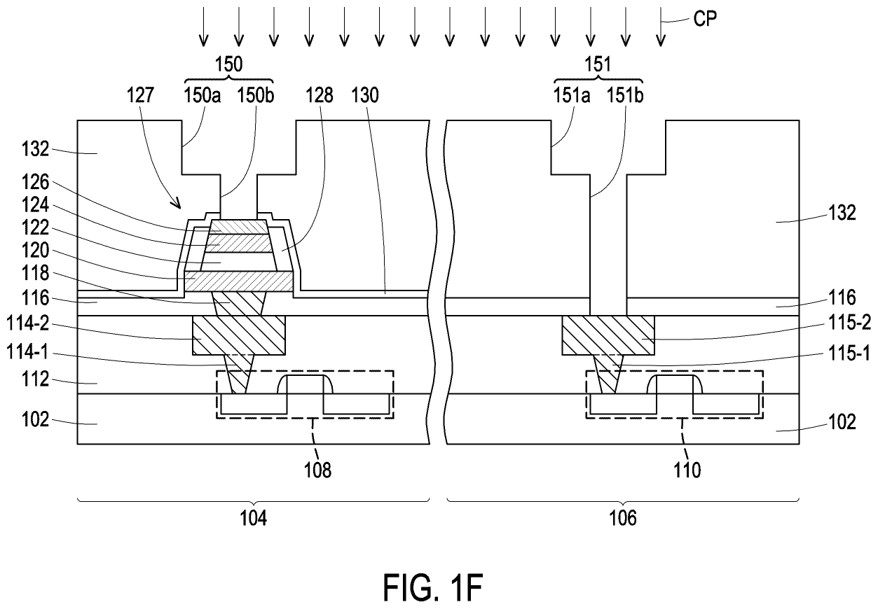

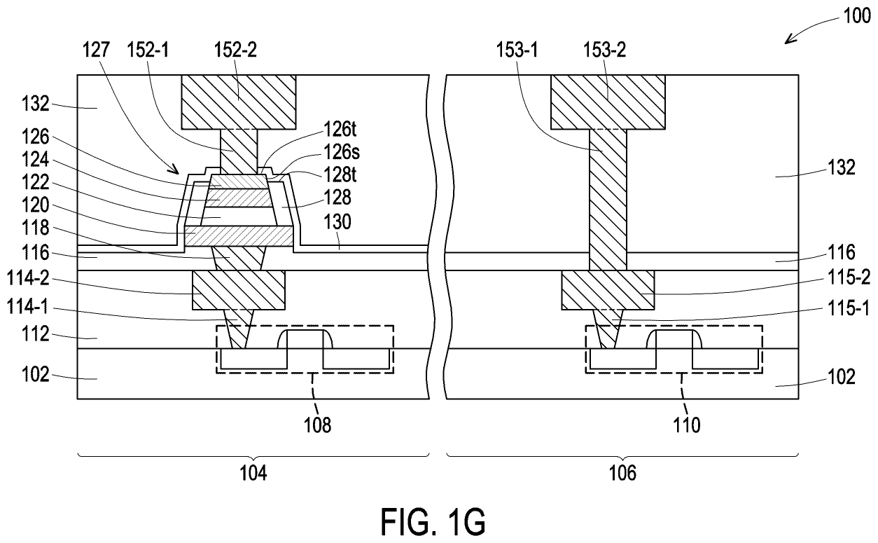

FIGS. 1A-1G are schematic cross-sectional views of various stages in a method of forming a semiconductor device according to some embodiments.

Referring to FIG. 1A, a substrate 102 is provided. In some embodiments, the substrate 102 is a bulk semiconductor substrate. A “bulk” semiconductor substrate refers to a substrate that is entirely composed of at least one semiconductor material. In some embodiments, the bulk semiconductor substrate includes a semiconductor material or a stack of semiconductor materials such as silicon (Si), germanium (Ge), silicon germanium (SiGe), carbon doped silicon (Si:C), silicon germanium carbon (SiGeC); or an III-V compound semiconductor such as gallium arsenide (GaAs), gallium phosphide (GaP), indium phosphide (InP), indium arsenide (InAs), indium antimonide (InSb), gallium arsenide phosphide (GaAsP), aluminum indium arsenide (AlInAs), aluminum gallium arsenide (AlGaAs), gallium indium arsenide (GaInAs), gallium indium phosphide (GaInP), or gallium indium arsenide phosphide (GaInAsP). In some embodiments, the bulk semiconductor substrate includes a single crystalline semiconductor material such as single crystalline silicon. In some embodiments, the bulk semiconductor substrate is doped depending on design requirements. In some embodiments, the bulk semiconductor substrate is doped with p-type dopants or n-type dopants. The term “p-type” refers to the addition of impurities to an intrinsic semiconductor that creates deficiencies of valence electrons. Exemplary p-type dopants, i.e., p-type impurities, include, but are not limited to, boron, aluminum, gallium, and indium. “N-type” refers to the addition of impurities that contribute free electrons to an intrinsic semiconductor. Exemplary n-type dopants, i.e., n-type impurities, include, but are not limited to, antimony, arsenic, and phosphorous. In some embodiments, the substrate 102 is a semiconductor-on-insulator (SOI) substrate including a top semiconductor layer formed on an insulator layer (not shown). The top semiconductor layer includes the above-mentioned semiconductor material such as Si, Ge, SiGe, Si:C, SiGeC; or an III-V compound semiconductor including GaAs, GaP, InP, InAs, InSb, GaAsP, AlInAs, AlGaAs, GaInAs, GaInP, or GaInASP. The insulator layer is, for example, a silicon oxide layer, or the like. The insulator layer is provided over a base substrate, typically a silicon or glass substrate.

In some embodiments, the substrate 102 includes a memory region 104 and a logic region 106. At least one device 108, 110 may be formed in and/or over the substrate 102 in the memory region 104 and the logic region 106. The device 108, 110 may be a transistor such as a MOSFET, a bi-polar junction transistor (BJT), a high electron mobility transistor (HEMT), or the like. For example, the device 108, 110 includes a gate structure, a source region and a drain region at opposite sides of the gate structure. The gate structure may include a gate dielectric layer, a gate electrode on the gate dielectric layer and spacers on opposite sidewalls of the gate dielectric layer and the gate electrode. However, the disclosure is not limited thereto.

A dielectric structure 112 is formed over the substrate 102 in the memory region 104 and the logic region 106, for example. The dielectric structure 112 may include a plurality of stacked inter-level dielectric (ILD) layers and a plurality of etch stop layers optionally and respectively formed therebelow. A material of the ILD layer may be silicon oxide, silicon nitride, silicon oxynitride, TEOS formed oxide, undoped silicate glass, doped silicate glass such as BPSG, FSG, PSG, BSG, the like or a combination thereof and may be formed by a deposition process such as CVD, PVD, ALD, the like or a combination thereof.

In some embodiments, a plurality of interconnect layers 114-1, 114-2, 115-1, 115-2 are disposed in the memory region 104 and the logic region 106. For example, the interconnect layers 114-1, 114-2, 115-1, 115-2 are formed in the dielectric structure 112 in the and stacked on one another. Each interconnect layer 114-1, 114-2, 115-1, 115-2 includes a via or a wire. For example, as shown in FIG. 1A, the interconnect layer 114-1, 115-1 includes a via and the interconnect layer 114-2, 115-2 includes a wire. The interconnect layer 114-1, 115-1 (e.g., via) is electrically coupled to the device 108, 110, and the interconnect layer 114-2, 115-2 (e.g., wire) is electrically coupled to the interconnect layer 114-1, 115-1. In some embodiments, the interconnect layer 114-2, 115-2 (e.g., wire) and the underlying interconnect layer 114-1, 115-1 (e.g., via) may be formed integrally or separately. The interconnect layer 114-1, 114-2, 115-1, 115-2 may include copper, aluminum, aluminum alloys, copper alloys, the like or a combination thereof and may be formed by using any suitable formation process (e.g., lithography with etching process or deposition and planarization processes). It is noted that although two stacked interconnect layers 114-1, 114-2 or 115-1, 115-2 are illustrated, there may be more interconnect layers over the device 108, 110. For example, the interconnect layer 114-2, 115-2 in FIG. 1A is also referred to as a metal four interconnect layer (e.g., M4 level) and the interconnect layer 114-1, 115-1 in FIG. 1A is also referred to as a via three interconnect layer (e.g., V3 level). In some embodiments (not shown), there may be more metal interconnect layers (e.g., metal one interconnect layer (e.g., M1 level), metal two interconnect layer (e.g., M2 level, M3 level) and metal three interconnect layer (e.g., M3 level)) and via interconnect layers (e.g., via zero interconnect layer (e.g., V0 level), via one interconnect layer (e.g., V1 level) and via two interconnect layer (e.g., V2 level)) between the interconnect layer 114-1 and the device 108 and between the interconnect layer 115-1 and the device 110.

In some embodiments, the interconnect layers 114-1, 114-2, 115-1, 115-2 in the memory region 104 and the interconnect layers 114-1, 114-2, 115-1, 115-2 in the logic region 106 may be formed simultaneously. For example, the interconnect layers 114-1, 115-1 in the memory region 104 and the logic region 106 are formed simultaneously, and the interconnect layers 114-2, 115-2 in the memory region 104 and the logic region 106 are formed simultaneously. The interconnect layer 114-1 in the memory region 104 and the interconnect layer 115-1 in the logic region 106 are substantially at the same level (e.g., height), and similarly, the interconnect layer 114-2 in the memory region 104 and the interconnect layer 115-2 in the logic region 106 are substantially at the same level (e.g., height).

In some embodiments, a dielectric layer 116 is formed over the dielectric structure 112 in the memory region 106 and the logic region 102. The dielectric layer 116 may be a single layer or a multi-layer structure. For example, the dielectric layer 116 includes a first layer such as silicide barrier layer (SBL) layer and a second layer such as silicon-rich oxide (SRO) layer on the first layer. Each layer may have a thickness in a range of between approximately 100 angstroms and approximately 200 angstroms. However, the disclosure is not limited thereto. In alternative embodiments, the dielectric layer 116 includes an extreme low-k dielectric material such as SiC. In some embodiments, the dielectric layer 116 may serve as an etch stop layer during the subsequent etching process.

In some embodiments, a bottom electrode via (BEV) 118 is formed in the dielectric layer 116 in the memory region 104 to electrically connect to the interconnect layer 114-2. In some embodiments, the bottom electrode via 118 includes copper, aluminum, aluminum alloys, copper alloys, the like or a combination thereof and is formed by using any suitable formation process (e.g., lithography with etching process or deposition and planarization processes).

Referring to FIG. 1B, a bottom electrode material 119, a data storage material 121, a top electrode material 123 and a metal electrode material 125 are sequentially formed over the substrate 102 in the memory region 104. The bottom electrode material 119 is formed on the dielectric layer 116 to cover the bottom electrode via 118, the data storage material 121 is formed on the bottom electrode material 119, the top electrode material 123 is formed on the data storage material 121, and the metal electrode material 125 is formed on the top electrode material 123. In some embodiments, the bottom electrode material 119, the data storage material 121, the top electrode material 123 and the metal electrode material 125 are formed in both the memory region 104 and the logic region 106. In alternative embodiments, the bottom electrode material 119, the data storage material 121, the top electrode material 123 and the metal electrode material 125 may be formed only in the memory region 104. The bottom electrode material 119, the data storage material 121, the top electrode material 123 and the metal electrode material 125 may be formed by CVD, PVD, electroless plating, electroplating, sputtering, the like or a combination thereof.

The bottom electrode material 119 may include tantalum, tantalum nitride, titanium, titanium nitride, the like or a combination thereof. The bottom electrode material 119 may be a single layer or a multilayer structure. For example, the bottom electrode material 119 includes a tantalum nitride material and a titanium nitride material on the tantalum nitride material. The bottom electrode material 119 may have a thickness in a range of between approximately 150 angstroms and approximately 250 angstroms. In some embodiments where the memory cell under manufacture is an MRAM cell, the data storage material 121 includes a magnetic tunnel junction (MTJ) material or other suitable magnetic storage structure. The MTJ material may include a first ferromagnetic material, a second ferromagnetic material and a MTJ barrier material between the first and second ferromagnetic materials. The first and second ferromagnetic materials may respectively include Fe, Co, Ni, FeCo, CoNi, CoFeB, FeB, FePt, FePd, or the like. The MTJ barrier material may include magnesium oxide (MgO), aluminum oxide (e.g., Al₂O₃), NiO, GdO, Ta₂O₅, MoO₂, TiO₂, WO₂, or the like. In alternative embodiments where the memory cell under manufacture is a RRAM cell, the data storage material 121 includes hafnium oxide, some other suitable high K dielectric(s), or some other suitable dielectric(s).

The top electrode material 123 and the metal electrode material 125 have different materials. In some embodiments, a free-energy change for an oxidation of the metal electrode material 125 is less than a free-energy change for an oxidation of the top electrode material 123. For example, the metal electrode material 125 has a higher oxidation resistance than the top electrode material 123. In some embodiments, the top electrode material 123 includes tungsten (W), the like or a combination thereof, and the metal electrode material 125 includes tantalum (Ta), molybdenum (Mo), ruthenium (Ru), platinum (Pt), iridium (Ir), metal nitride thereof, the like or a combination thereof. The free-energy change for an oxidation may be represented by Gibbs free energy, Gibbs free energy of tungsten (W) is about −834 kJ/mol, and Gibbs free energy of ruthenium (Ru) is about −313.9 kJ/mol. The top electrode material 123 has a thickness in a range of between approximately 150 angstroms and approximately 250 angstroms, for example. The metal electrode material 125 has a thickness in a range of between approximately 50 angstroms and approximately 150 angstroms, for example.

Referring to FIG. 1C and FIG. 1D, a bottom electrode 120, a data storage layer 122, a top electrode 124 and a metal electrode 126 are formed. In some embodiments, the bottom electrode 120, the data storage layer 122, the top electrode 124 and the metal electrode 126 form a memory cell 127, and a spacer 128 is formed on a sidewall of the memory cell 127. In some embodiments, the memory cell 127 is a MRAM cell. In alternative embodiments, the memory cell 127 is a RRAM cell, a phase change random access memory (PCRAM) cell, a ferroelectric random access memory (FRAM) cell, a programmable metallization memory cell, a carbon nanotube memory cell, or the like.

In some embodiments, as shown in FIG. 1C, the data storage material 121, the top electrode material 123 and the metal electrode material 125 are simultaneously patterned by using a same mask, to form the data storage layer 122, the top electrode 124 and the metal electrode 126. The patterning process may include lithography with etching process. Then, a spacer material (not shown) may be deposited on the bottom electrode material 119 and a stack of the data storage layer 122, the top electrode 124 and the metal electrode 126 using a deposition technique (e.g., PVD, CVD, PE-CVD, ALD and sputtering) and then be partially removed by an anisotropic etch, so as to form the spacer 128 as shown in FIG. 1D. The spacer 128 may include silicon nitride, silicon dioxide (SiO₂), silicon oxy-nitride (SiON), or the like. Then, by using the spacer 128 and the stack of the data storage layer 122, the top electrode 124 and the metal electrode 126 as a mask, the bottom electrode material 119 is patterned, to form the bottom electrode 120. The patterning process may include lithography with etching process. Thus, the memory cell 127 is formed.

In some embodiments, the spacer 128 is disposed on the bottom electrode 120 and covers sidewalls 122s, 124s, 126s of the data storage layer 122, the top electrode 124 and the metal electrode 126. Thus, the spacer 128 surrounds the data storage layer 122, the top electrode 124 and the metal electrode 126. In some embodiments, the sidewalls 122s, 124s, 126s of the data storage layer 122, the top electrode 124 and the metal electrode 126 are substantially flush with one another. The sidewall 120s of the bottom electrode 120 may be substantially flush with an outer sidewall 128s of the spacer 128, and extends beyond the sidewalls 122s, 124s, 126s of the data storage layer 122, the top electrode 124 and the metal electrode 126. The metal electrode 126 covers a top surface 124t of the top electrode 124, and thus the top electrode 124 is not exposed. In some embodiments, a top surface 128t of the spacer 128 is lower than a top surface 126t of the metal electrode 126, and thus a portion of the sidewall 126s of the metal electrode 126 is exposed by the spacer 128. However, the disclosure is not limited thereto. The memory cell 127 may have any suitable configuration.

The memory cell 127 is configured to store a data state based upon a resistive value of the memory cell 127. For example, the memory cell 127 stores a first data state (e.g., a logical “0”) when the memory cell 127 has a low resistance state or a second data state (e.g., a logical “1”) when the memory cell 127 has a high resistance state. During operation, the data storage layer 122 may be changed between the low resistance state and the high resistance state through the tunnel magnetoresistance (TMR) effect.

In some embodiments, during the formation of the spacer 128, portions of the exposed dielectric layer 116 may be removed. In some embodiments, as shown in FIG. 1D, in both the memory region 104 and the logic region 106, a top surface 116t′ of the exposed dielectric layer 116 may be lower than a top surface 116t of the dielectric layer 116 covered by the memory cell 127.

Referring to FIG. 1E, in some embodiments, an etch stop layer 130 is formed over the substrate 102. For example, the etch stop layer 130 is formed on the dielectric layer 116 and covers the dielectric layer 116 and the memory cell 127. In some embodiments, the etch stop layer 130 is in direct contact with the top surface 116t′ of the dielectric layer 116, the sidewalls 120s, 128s of the bottom electrode 120 and the spacer 128, and the top surfaces 128t, 126t of the spacer 128 and the metal electrode 126. In some embodiments, since the sidewall 126s of the metal electrode 126 is partially exposed by the spacer 128, the etch stop layer 130 is further in direct contact with the sidewall 126s of the metal electrode 126. In some embodiments, the etch stop layer 130 is formed in both the memory region 104 and the logic region 106, and then removed from the logic region 106. The etch stop layer 130 may include silicon carbide, silicon nitride, the like or a combination thereof and be formed by a suitable deposition process such as CVD, PVD, ALD, the like or a combination thereof. In alternative embodiments, the etch stop layer 130 may be omitted or have any suitable configuration.

As shown in FIG. 1E, after the etch stop layer 130 is formed, a dielectric structure 132 is formed over the substrate 102 to cover the memory region 104 and the logic region 106. The dielectric structure 132 may include a plurality of stacked inter-level dielectric (ILD) layers and a plurality of etch stop layers optionally and respectively formed therebelow. A material of the ILD layer may be silicon oxide, silicon nitride, silicon oxynitride, TEOS formed oxide, undoped silicate glass, doped silicate glass such as BPSG, FSG, PSG, BSG, the like or a combination thereof and may be formed by a deposition process such as CVD, PVD, ALD, the like or a combination thereof.

Referring to FIG. 1F, an opening 150 is formed in the dielectric structure 132 in the memory region 104, and an opening 151 is formed in the dielectric structure 132 in the logic region 106. In some embodiments, the opening 150 penetrates the dielectric structure 132 to expose the metal electrode 126, and the opening 151 penetrates the dielectric structure 132 and the dielectric layer 116 to expose the interconnect layer 115-2. In some embodiments, the opening 150 and the opening 151 are formed simultaneously by using a same etching process. For example, portions of the dielectric structure 132 are simultaneously removed from both the memory region 104 and the logic region 106 by the same etchant. The opening 150 and the opening 151 may be formed by using a damascene process such as a dual damascene process. For example, the opening 150 and the opening 151 respectively include a via opening 150a, 151a and a trench opening 150b, 151b connected to the via opening 150a, 151a. However, the disclosure is not limited. The opening 150 and the opening 151 may be formed separately or have any suitable configuration. In alternative embodiments, the via opening 150a, 151a and the trench opening 150b, 151b are disposed in different ILD layers. In such embodiments, the via opening 150a, 151a is disposed in a first ILD layer, the trench opening 150b, 151b is disposed in a second ILD layer over the first ILD layer, and an etch stop layer is optionally and respectively disposed under the first ILD layer and the second ILD layer.

In some embodiments, during the etching process of the opening 150 and the opening 151, etch by-products may be generated. Therefore, after formation of the opening 150 and the opening 151, a cleaning process CP may be simultaneously performed to the memory region 104 and the logic region 106 with a cleaning solution, to remove the etch by-products. In some embodiments, the cleaning process CP is a wet cleaning process and uses an acidic solution containing hydrogen peroxide (H₂O₂) as the cleaning solution, for example. In an embodiment in which the metal electrode 126 is absent and the top electrode 124 is exposed by the opening 150, an erosion of the exposed top electrode 124 may be occurred due to an oxidation reaction between the metal (e.g., tungsten) of the top electrode 124 and the oxidant (e.g., hydrogen peroxide) in the cleaning solution. For example, when tungsten (W) of the top electrode 124 reacts with hydrogen peroxide (H₂O₂) in the cleaning solution, tungsten oxide (WO₄²⁻) is formed and thus a hollow is formed at the top of the top electrode 124. The erosion may be also referred to as a wet chemical erosion. In such embodiments, the MRAM cell may be open-failed. In an embodiment in which the metal electrode 126 is absent and the top electrode 124 is exposed by the opening 150, the erosion is prevented by using the cleaning solution without hydrogen peroxide, however, the cleaning solution may affect the break down voltage of the logic region 106.

In some embodiments, since the metal electrode 126 is formed to cover the top electrode 124 and has a higher free-energy change for an oxidation than the top electrode 124, the metal electrode 126 prevents the top electrode 124 from being eroded by the cleaning solution during the cleaning process CP. Accordingly, the performance of both the memory region 104 and the logic region 106 is improved. Furthermore, the cleaning process CP using the cleaning solution (e.g., containing hydrogen peroxide) may be compatible to both the memory region 104 and the logic region 106, and thus cost and time may be saved. In some embodiments, the metal electrode 126 does not or substantially does not react with the cleaning solution, and the metal electrode 126 is also referred to as inert top electrode.

Referring to FIG. 1G, interconnect layers 152-1, 152-2, 153-1, 153-2 are formed in the openings 150, 151. In some embodiments, the interconnect layers 152-1, 152-2 in the memory region 104 and the interconnect layers 153-1, 153-2 in the logic region 106 are formed simultaneously. For example, the interconnect layers 152-1, 153-1 in the memory region 104 and the logic region 106 are formed simultaneously, and the interconnect layers 152-2, 153-2 in the memory region 104 and the logic region 106 are formed simultaneously. A top surface of the interconnect layer 152-1 in the memory region 104 and a top surface of the interconnect layer 153-1 in the logic region 106 are substantially at the same level (e.g., height), and similarly, the interconnect layer 152-2 in the memory region 104 and the interconnect layer 153-2 in the logic region 106 are substantially at the same level (e.g., height). Each interconnect layer 152-1, 152-2, 153-1, 153-2 may include copper, aluminum, aluminum alloys, copper alloys, the like or a combination thereof and may be formed by using any suitable process. For example, a conductive material is formed to fill up the openings 150, 151 by a deposition process such as CVD, PVD or ALD, and a planarization process such as a chemical mechanical planarization (CMP) process is performed to remove the excess conductive material outside the openings 150, 151.

Each interconnect layer 152-1, 152-2, 153-1, 153-2 includes a via or a wire. For example, as shown in FIG. 1G, the interconnect layer 152-1, 153-1 include a via and the interconnect layer 152-2, 153-2 include a wire. In some embodiments, the interconnect layer 152-1, 153-1 is formed in the via opening 150a, 151a, and the interconnect layer 152-2, 153-2 is formed in the trench opening 150b, 151b. The interconnect layer 152-2 (e.g., wire) is electrically coupled to the memory cell 127 through the interconnect layer 152-1 (e.g., via) and the metal electrode 126, for example. The interconnect layer 152-1 is also referred to as a top electrode via (TEV). The interconnect layer 153-2 (e.g., wire) is electrically coupled to the interconnect layer 115-2 through the interconnect layer 153-1 (e.g., via), for example. In some embodiments, the interconnect layer 152-2, 153-2 (e.g., wire) and the underlying interconnect layer 152-1, 153-1 (e.g., via) may be formed integrally or separately. It is noted that although only two stacked interconnect layers 152-1, 152-2 or 153-1, 153-2 are illustrated, there may be more interconnect layers over the memory cell 127 or the interconnect layer 115-2. For example, the interconnect layer 152-2, 153-2 in FIG. 1G is also referred to as a metal five interconnect layer (e.g., M5 level) and the interconnect layer 152-1, 153-1 in FIG. 1G is also referred to as a via four interconnect layer (e.g., V4 level). In some embodiments (not shown), there may be more interconnect layers over the interconnect layer 152-2, 153-2.

In some embodiments, a semiconductor device 100 includes the memory cell 127, and the metal electrode 126 of the memory cell 127 protects the top electrode 124 from being eroded. Accordingly, the memory cell 127 may have an improved performance. In addition, since the cleaning solution containing the oxidant (e.g., H₂O₂) may be used in the cleaning process, the electrical performance of the logic region may be maintained. Thus, both the memory region and the logic region may have an improved performance.

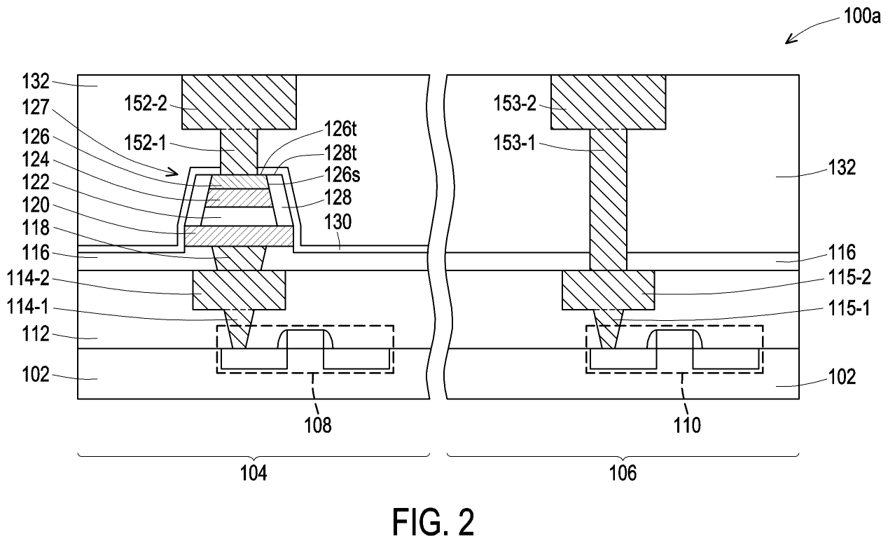

In some embodiments, the top surface 128t of the spacer 128 is lower than the top surface 126t of the metal electrode 126, and thus a portion of the sidewall 126s of the metal electrode 126 is exposed by the spacer 128. However, the disclosure is not limited thereto. In some embodiments, as shown in the semiconductor device 100a of FIG. 2, the top surface 128t of the spacer 128 is substantially coplanar with the top surface 126t of the metal electrode 126. In such embodiments, the sidewall 126s of the metal electrode 126 is entirely covered by the spacer 128. As shown in FIG. 2, the etch stop layer 130 only contacts the top surface of the top surface 126t of the metal electrode 126 and does not contact the sidewall 126s of the metal electrode 126.

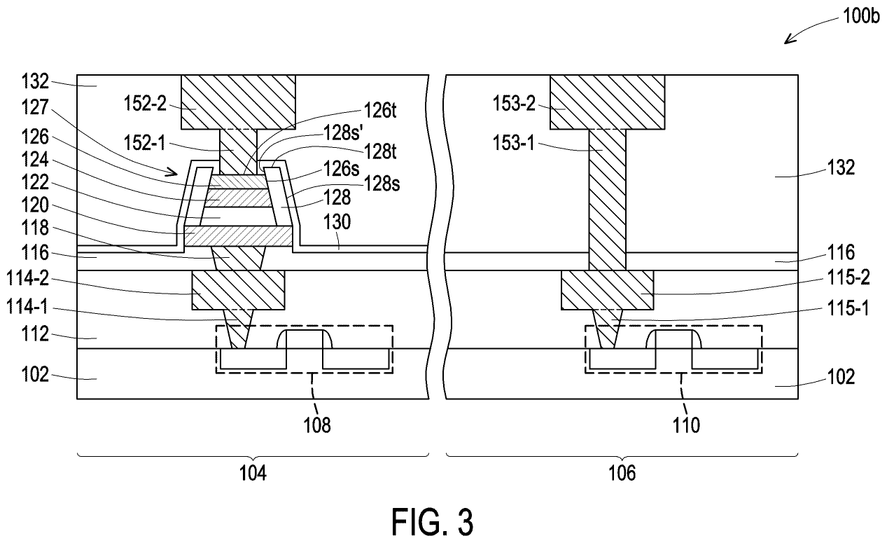

In alternative embodiments, as shown in the semiconductor device 100b of FIG. 3, the top surface 128t of the spacer 128 is higher than the top surface 126t of the metal electrode 126. In such embodiments, the sidewall 126s of the metal electrode 126 is also entirely covered by the spacer 128. As shown in FIG. 3, the etch stop layer 130 may further cover a portion of an inner sidewall 128s′ of the spacer 128. In other words, the etch stop layer 130 is disposed on both the outer sidewall 128s and the inner sidewall 128s′ of the spacer 128.

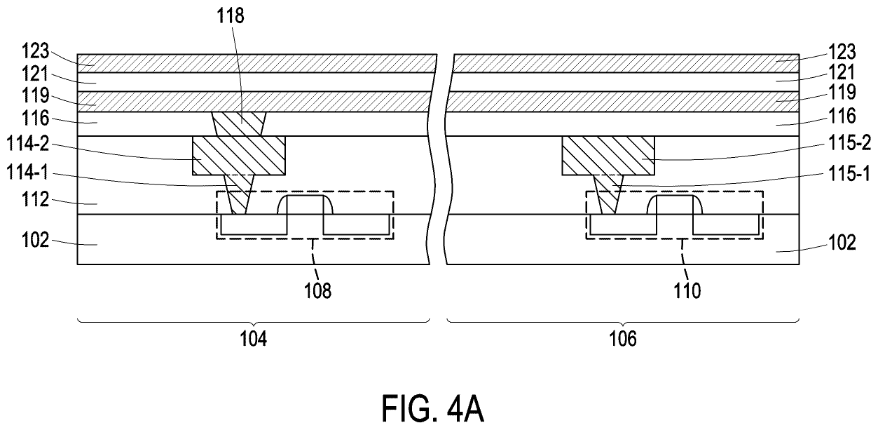

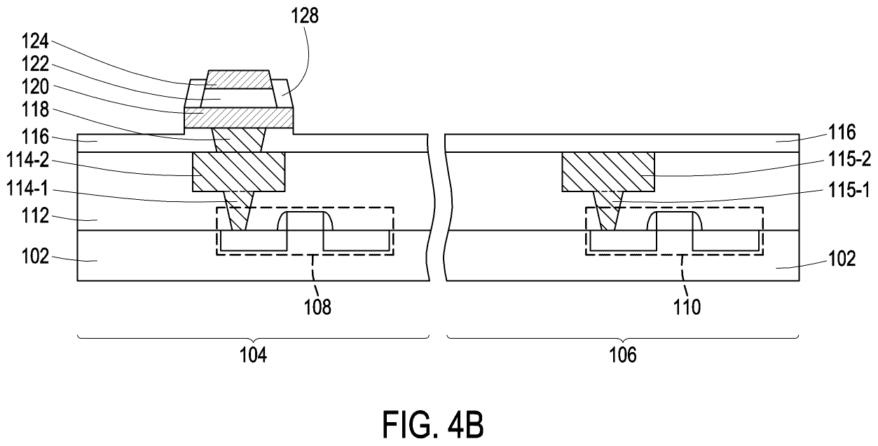

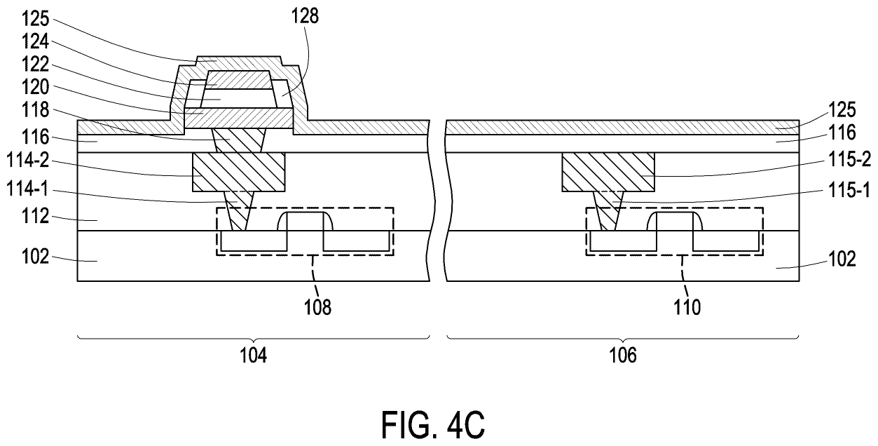

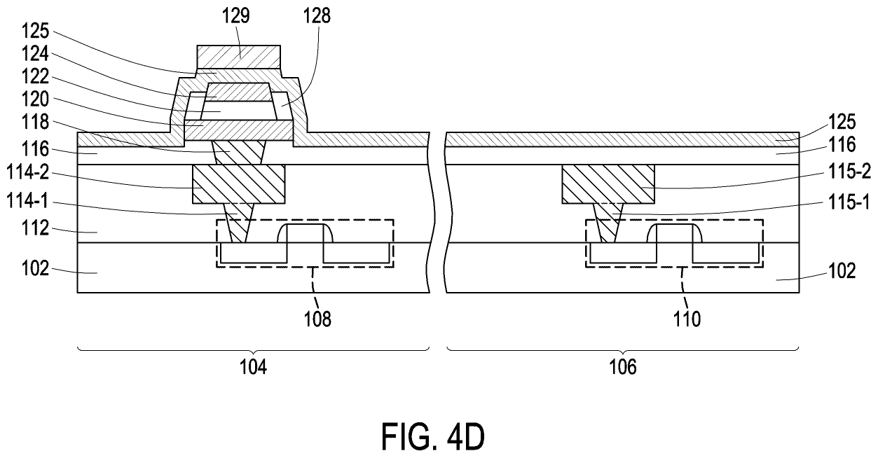

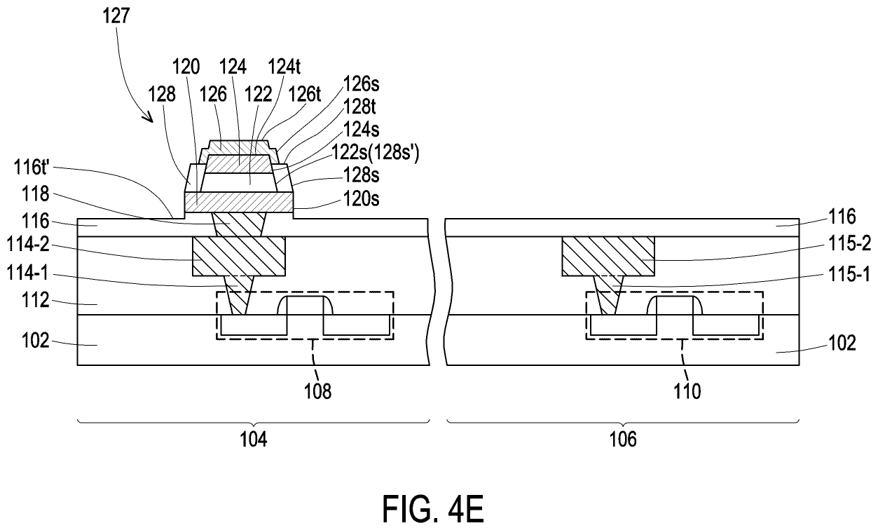

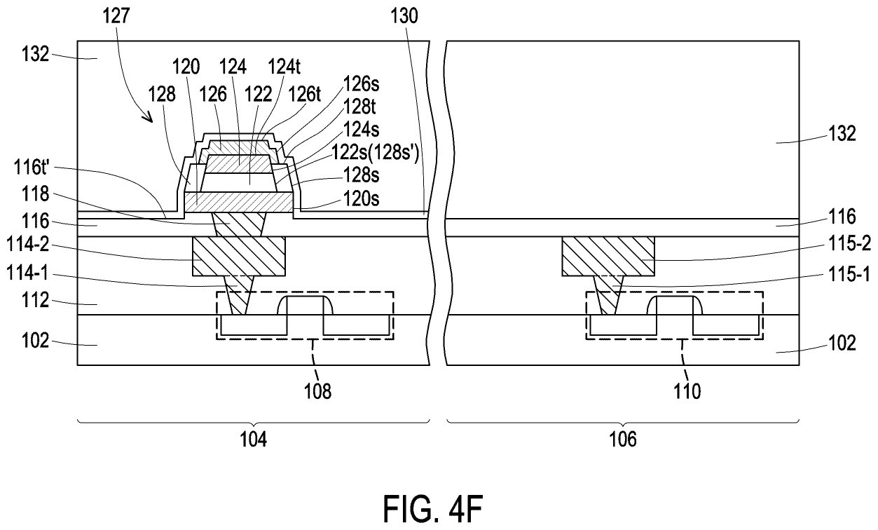

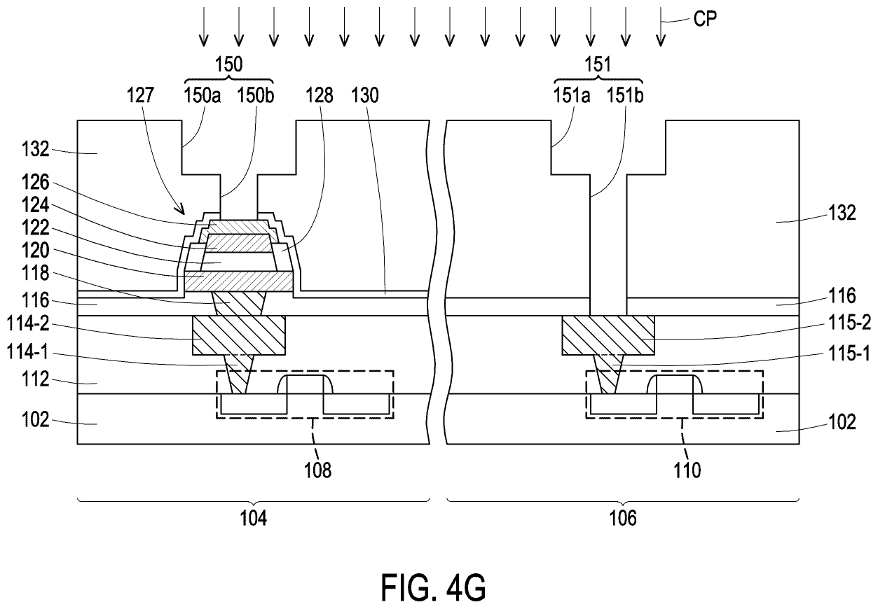

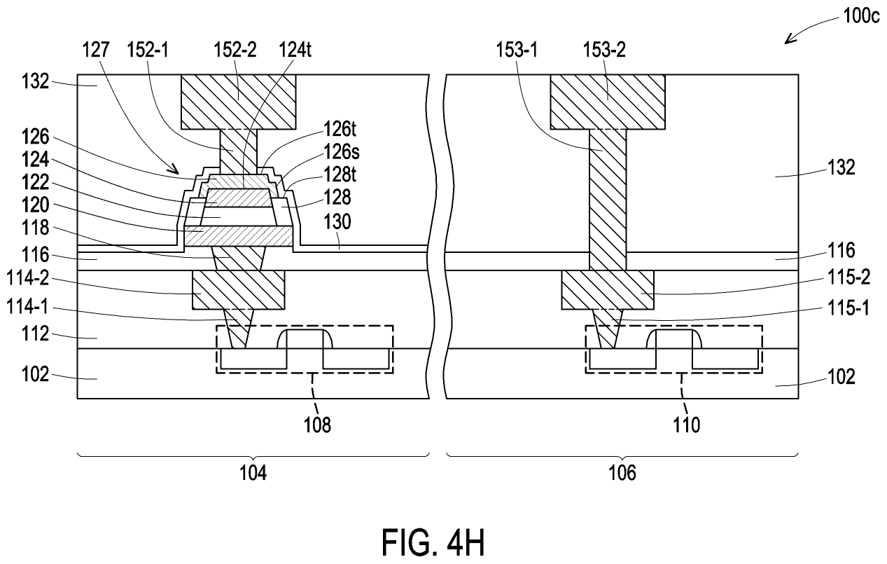

FIGS. 4A-4H are schematic cross-sectional views of various stages in a method of forming a semiconductor device according to some embodiments. The difference between the method of FIGS. 4A-4H and the method of FIG. 1A-1G lies in that the metal electrode is formed after the spacer is formed.

Referring to FIG. 4A, a bottom electrode material 119, a data storage material 121 and a top electrode material 123 are sequentially formed over a substrate 102 in a memory region 104. The materials, arrangement and forming methods of the substrate 102, the devices 108, 110, the dielectric structure 112, the interconnect layers 114-1, 114-2, 115-1, 115-2, the dielectric layer 116, the BEV 118, the bottom electrode material 119, the data storage material 121 and the top electrode material 123 may be similar to those described with reference to FIGS. 1A and 1B, so the detailed descriptions thereof are omitted herein.

Referring to FIG. 4B, a bottom electrode 120, a data storage layer 122, a top electrode 124 and a spacer 128 are formed. In some embodiments, by using a mask, the data storage material 121 and the top electrode material 123 are patterned, to form the data storage layer 122 and the top electrode 124. The patterning process may include lithography with etching process. Then, a spacer material (not shown) may be deposited on the bottom electrode material 119 and a stack of the data storage layer 122 and the top electrode 124 using a deposition technique (e.g., PVD, CVD, PE-CVD, ALD and sputtering) and then be partially removed by an anisotropic etch, so as to form the spacer 128. The spacer 128 may include silicon nitride, silicon dioxide (SiO₂), silicon oxy-nitride (SiON), or the like. Then, by using the spacer 128 and the stack of the data storage layer 122 and the top electrode 124 as a mask, the bottom electrode material 119 is patterned, to form the bottom electrode 120.

Referring to FIG. 4C, after the formation of the spacer 128, a metal electrode material 125 is formed over the bottom electrode 120, the data storage layer 122, the top electrode 124 and the spacer 128. In some embodiments, the metal electrode material 125 is conformally formed over the dielectric layer 116, the bottom electrode 120, the data storage layer 122, the top electrode 124 and the spacer 128. The materials and forming methods of the metal electrode material 125 may be similar to those described with reference to FIG. 1B, so the detailed descriptions thereof are omitted herein.

Referring to FIG. 4D and FIG. 4E, a metal electrode 126 is formed by patterning the metal electrode material 125. In some embodiments, as shown in FIG. 4D, a mask 129 is formed on the metal electrode material 125. The mask 129 may have a width not larger than a total width of the top electrode 124 and the spacer 128 on opposite sides of top electrode 124. Then, as shown in FIG. 4E, a portion of the metal electrode material 125 is removed to form the metal electrode 126, and the mask 129 is removed. The patterning process may include lithography with etching process. Then, the memory cell 127 including the bottom electrode 120, the data storage layer 122, the top electrode 124 and the metal electrode 126 is formed. In some embodiments, the patterning process of the metal electrode material 125 is performed after the patterning process of the data storage material 121 and the top electrode material 123 and after the formation of the spacer 128.

In some embodiments, as shown in FIG. 4E, sidewalls 122s, 124s of the data storage layer 122 and the top electrode 124 are substantially flush with one another, and a sidewall 126s (i.e., outer sidewall) of the metal electrode 126 extends beyond the sidewalls 122s, 124s of the data storage layer 122 and the top electrode 124. In some embodiments, the metal electrode 126 covers not only the top surface 124t of the top electrode 124 but also the sidewall 124s of the top electrode 124. The metal electrode 126 is conformal to the spacer 128 and the top electrode 124, for example. The top surface 124t of the top electrode 124 is higher than the top surface 128t of the spacer 128, for example. In some embodiments, the metal electrode 126 is disposed on (extended onto) the top surface 128t of the spacer 128. That is, the top surface 128t of the spacer 128 may be partially covered by the metal electrode 126, and the top surface 126t of the metal electrode 126 is higher than the top surface 128t of the spacer 128. In some embodiments, the outer sidewall 126s of the metal electrode 126 is inside an outer sidewall 128s of the spacer 128. For example, the outer sidewall 126s of the metal electrode 126 is disposed between an inner sidewall 128s′ and the outer sidewall 128s of the spacer 128. However, the disclosure is not limited thereto.

Referring to FIG. 4F, in some embodiments, an etch stop layer 130 is formed over the substrate 102, and a dielectric structure 132 is formed over the substrate 102 to cover the memory region 104 and the logic region 106. For example, the etch stop layer 130 is conformally formed on and covers the dielectric layer 116 and the memory cell 127. In some embodiments, the etch stop layer 130 is in direct contact with the top surface 116t′ of the dielectric layer 116, the sidewalls 120s, 128s, 126s of the bottom electrode 120, the spacer 128 and the metal electrode 126, and the top surfaces 128t, 126t of the spacer 128 and the metal electrode 126. The materials and forming methods of the etch stop layer 130 and the dielectric structure 132 may be similar to those described with reference to FIG. 1E, so the detailed descriptions thereof are omitted herein.

Referring to FIG. 4G, an opening 150 is formed in the dielectric structure 132 in the memory region 104, and an opening 151 is formed in the dielectric structure 132 in the logic region 106. Then, a cleaning process CP may be performed to the memory region 104 and the logic region 106, to remove etch by-products formed during the formation of the openings 150, 151. The forming methods of the openings 150, 151 and the cleaning process CP may be similar to those described with reference to FIG. 1F, so the detailed descriptions thereof are omitted herein. In some embodiments, similar to that described in reference with FIG. 1F, since the metal electrode 126 is formed to cover the top electrode 124 and has a higher free-energy change for an oxidation than the top electrode 124, the metal electrode 126 prevents the top electrode 124 from being eroded by the cleaning solution during the cleaning process CP. Accordingly, the performance of both the memory region 104 and the logic region 106 is improved. Furthermore, the cleaning process CP using the cleaning solution (e.g., containing hydrogen peroxide) may be compatible to both the memory region 104 and the logic region 106, and thus cost and time may be saved.

Referring to FIG. 4H, interconnect layers 152-1, 152-2, 153-1, 153-2 are formed in the openings 150, 151. The materials and forming methods of the interconnect layers 152-1, 152-2, 153-1, 153-2 may be similar to those described with reference to FIG. 1G, so the detailed descriptions thereof are omitted herein.

In some embodiments, a semiconductor device 100c includes the memory cell 127, and the metal electrode 126 of the memory cell 127 protects the underlying top electrode 124 from being eroded. Accordingly, the memory cell 127 may have an improved performance. In addition, since the cleaning solution containing the oxidant (e.g., H₂O₂) may be used in the cleaning process, the electrical performance of the logic region may be maintained. Thus, both the memory region and the logic region may have an improved performance.

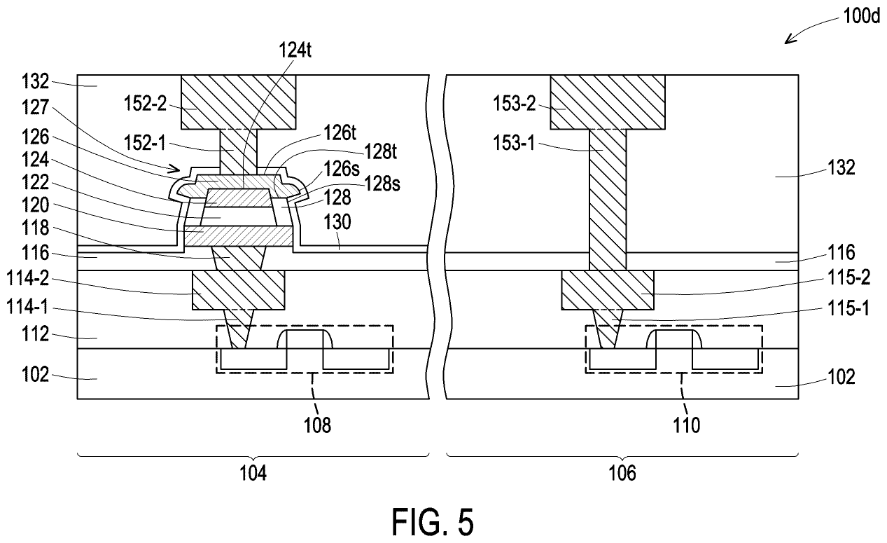

In some embodiments, a portion of the top surface 128t of the spacer 128 is exposed by the metal electrode 126. However, the disclosure is not limited thereto. In some embodiments, as shown in the semiconductor device 100d of FIG. 5, the top surface 128t of the spacer 128 is entirely covered by the metal electrode 126, and thus the etch stop layer 130 does not contact the top surface 128t of the spacer 128. In such embodiments, the sidewall (i.e., outermost sidewall) 126s of the metal electrode 126 extends beyond the outer sidewall 128s of the spacer 128. The metal electrode 126 is hat-shaped, for example.

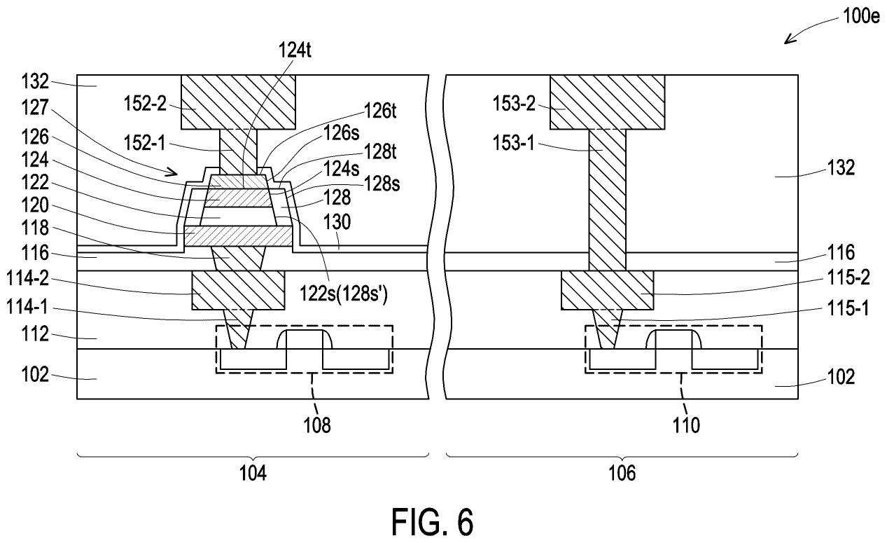

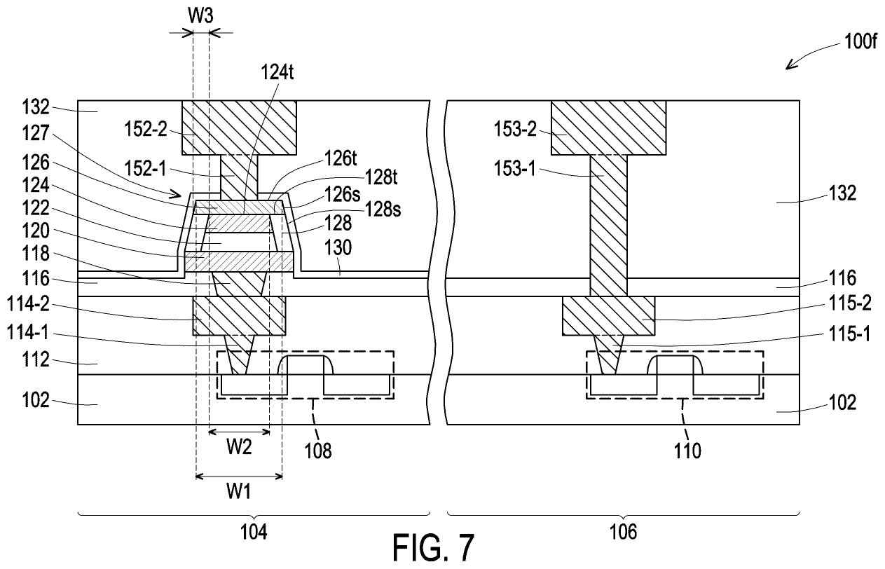

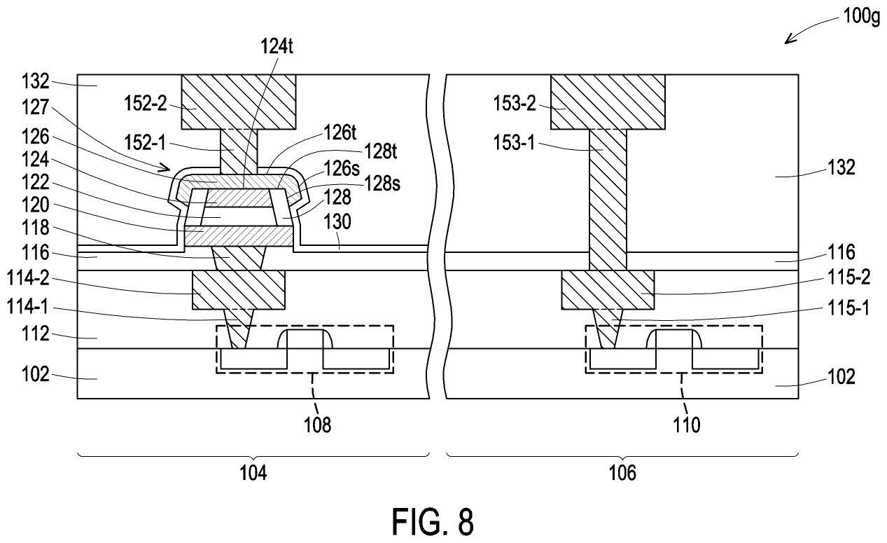

In some embodiments, the top surface 128t of the spacer 128 is lower than the top surface 124t of the top electrode 124. However, the disclosure is not limited thereto. In some embodiments, as shown in the semiconductor devices 100e of FIG. 6, 100f of FIG. 7 and 100g of FIG. 8, the top surface 128t of the spacer 128 is substantially coplanar with the top surface 124t of the top electrode 124. As shown in FIG. 6, the sidewall 126s of the metal electrode 126 may be substantially flush with the inner sidewall 128s′ of the spacer 128 and the sidewalls 122s, 124s of the data storage layer 122 and the top electrode 124. It is noted that the structure of memory cell 127 in FIG. 6 may be formed by using the method of FIG. 1A to FIG. 1D or the method of FIG. 4A to FIG. 4E. That is, the patterning process of the metal electrode material 125 may be performed simultaneously with or after the patterning process of the data storage material 121 and the top electrode material 123.

In some embodiments, as shown in FIG. 7, the sidewall 126s of the metal electrode 126 may be substantially flush with the outer sidewall 128s of the spacer 128. For example, a width W1 of the metal electrode 126 is larger than a width W2 of the top electrode 124. The width W1 may be substantially equal to a total width (e.g., W2+2*W3) of a width W2 of the top electrode 124 and a total width (e.g., 2*W3) of the spacer 128 on opposite sides of the top electrode 124. In some embodiments, as shown in FIG. 8, the metal electrode 126 may further extend onto the outer sidewall 128s of the spacer 128.

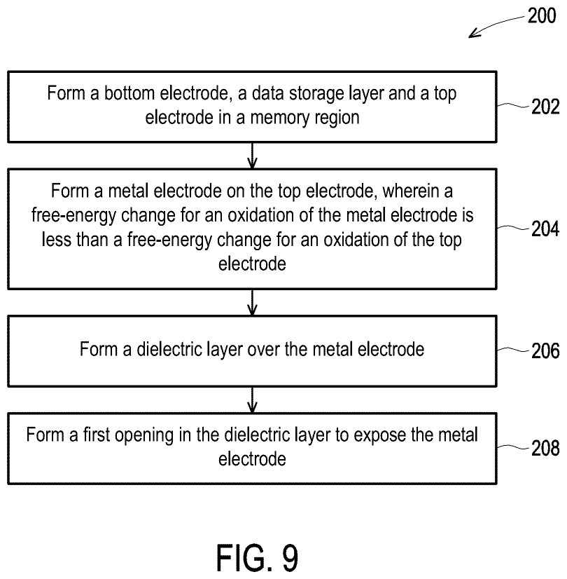

FIG. 9 illustrates a flowchart of a method of forming a semiconductor device according to some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 202, a bottom electrode, a data storage layer and a top electrode are formed in a memory region. FIGS. 1A-1D and FIGS. 4A-4B illustrate views corresponding to some embodiments of act 202.

At act 204, a metal electrode is formed on the top electrode, wherein a free-energy change for an oxidation of the metal electrode is less than a free-energy change for an oxidation of the top electrode. FIGS. 1A-1D and FIGS. 4C-4E illustrate views corresponding to some embodiments of act 204.

At act 206, a dielectric layer is formed over the metal electrode. FIG. 1E and FIG. 4F illustrate views corresponding to some embodiments of act 206.

At act 208, a first opening is formed in the dielectric layer to expose the metal electrode. FIG. 1F and FIG. 4G illustrate views corresponding to some embodiments of act 208.

According to some embodiments, a semiconductor device includes a bottom electrode, a data storage layer, a top electrode and a metal electrode. A free-energy change for an oxidation of the metal electrode is less than a free-energy change for an oxidation of the top electrode.

According to some embodiments, a semiconductor device includes a memory cell. The memory cell includes a bottom electrode, a data storage layer, a top electrode, a metal electrode and a spacer. The data storage layer is disposed on the bottom electrode. The top electrode is disposed on the data storage layer. The metal electrode is disposed on the top electrode. The spacer surrounds the top electrode, and the metal electrode is disposed on a top surface of the spacer. A free-energy change for an oxidation of the metal electrode is less than a free-energy change for an oxidation of the top electrode.

According to some embodiments, a method of forming a semiconductor device includes following steps. A bottom electrode, a data storage layer and a top electrode are formed in a memory region. A metal electrode on the top electrode is formed on the top electrode, wherein a free-energy change for an oxidation of the metal electrode is less than a free-energy change for an oxidation of the top electrode. A dielectric layer is formed over the metal electrode. A first opening is formed in the dielectric layer to expose the metal electrode.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a bottom electrode;
a data storage layer;
a top electrode; and
a metal electrode,
wherein a free-energy change for an oxidation of the metal electrode is less than a free-energy change for an oxidation of the top electrode.

2. The semiconductor device of claim 1, wherein
the data storage layer is disposed on the bottom electrode;
the top electrode is disposed on the data storage layer; and
the metal electrode is disposed on the top electrode.

3. The semiconductor device of claim 1, wherein a sidewall of the metal electrode is substantially flush with a sidewall of the top electrode.

4. The semiconductor device of claim 1, further comprising a spacer disposed on the bottom electrode and surrounding the data storage layer and the top electrode.

5. The semiconductor device of claim 4, further comprising an etch stop layer on sidewalls of the metal electrode and the spacer.

6. The semiconductor device of claim 1, further comprising an etch stop layer in direct contact with the metal electrode.

7. The semiconductor device of claim 1, wherein
the top electrode comprises Tungsten (W); and
the metal electrode comprises Tantalum (Ta), Molybdenum (Mo), Ruthenium (Ru), Platinum (Pt), Iridium (Ir), metal nitride thereof or a combination thereof.

8. A semiconductor device, comprising:
a memory cell, comprising:
a bottom electrode;
a data storage layer on the bottom electrode;
a top electrode on the data storage layer;
a metal electrode on the top electrode; and
a spacer surrounding the top electrode, wherein the metal electrode is disposed on a top surface of the spacer,
wherein a free-energy change for an oxidation of the metal electrode is less than a free-energy change for an oxidation of the top electrode.

9. The semiconductor device of claim 8, wherein the spacer is disposed on the bottom electrode and further surrounds the data storage layer.

10. The semiconductor device of claim 8, wherein the metal electrode is further extended onto a sidewall of the top electrode.

11. The semiconductor device of claim 8, wherein an outer sidewall of the metal electrode is inside an outer sidewall of the spacer.

12. The semiconductor device of claim 8, wherein an outer sidewall of the metal electrode extends beyond an outer sidewall of the spacer.

13. The semiconductor device of claim 8, wherein an outer sidewall of the metal electrode is substantially flush with an outer sidewall of the spacer.

14. The semiconductor device of claim 8, further comprising an etch stop layer on sidewalls of the spacer and the metal electrode.

15. The semiconductor device of claim 8, wherein:
the top electrode comprises Tungsten (W); and
the metal electrode comprises Tantalum (Ta), Molybdenum (Mo), Ruthenium (Ru), Platinum (Pt), Iridium (Ir), metal nitride thereof or a combination thereof.

16. A method of forming a semiconductor device, comprising:
forming a bottom electrode, a data storage layer and a top electrode in a memory region;
forming a metal electrode on the top electrode, wherein a free-energy change for an oxidation of the metal electrode is less than a free-energy change for an oxidation of the top electrode;
forming a dielectric layer over the metal electrode; and
forming a first opening in the dielectric layer to expose the metal electrode.

17. The method of claim 16, wherein forming the bottom electrode, the data storage layer, the top electrode and the metal electrode comprises:
forming a data storage material on a bottom electrode material;
forming a top electrode material on the data storage material;
forming a metal electrode material on the top electrode material;
simultaneously patterning the data storage material, the top electrode material and the metal electrode material, to form the data storage layer, the top electrode and the metal electrode;
forming a spacer on sidewalls of the data storage layer, the top electrode and the metal electrode; and
by using the spacer and a stack of the data storage layer, the top electrode and the metal electrode as a mask, patterning the bottom electrode material.

18. The method of claim 16, wherein forming the metal electrode comprises:
forming a spacer on sidewalls of the data storage layer and the top electrode;
forming a metal electrode material over the top electrode and the spacer; and
patterning the metal electrode material to form the metal electrode.

19. The method of claim 16, further comprising:
forming the first opening in the dielectric layer in the memory region and a second opening in the dielectric layer in a logic region by an etching process; and
performing a cleaning process on the first opening and the second opening with a cleaning solution including an oxidant, to remove etch by-products formed during the etching process.

20. The method of claim 19, further comprising simultaneously forming a first interconnecting layer in the first opening and a second interconnecting layer in the second opening.
